(19) United States
(12) Patent Application Publication
(10) Pub. No.: US 2026/0304790 A1
(43) Pub. Date: Oct. 1, 2026

(54) High-Efficiency Embedded Active Component for Enhanced Channel Loss Compensation

(71) Applicant: Micron Technology, Inc., Boise, ID (US)

(72) Inventors: Ataul M. Karim, Boise, ID (US); Timothy M. Hollis, Meridian, ID (US)

(21) Appl. No.: 19/532,542

(22) Filed: Feb. 6, 2026

Related U.S. Application Data
(60) Provisional application No. 63/780,890, filed on Mar. 31, 2025.

(51) Int. Cl. H10B 80/00; H10W 70/60; H10W 70/63; H10W 90/00; H10W 90/10

(52) U.S. Cl. CPC H10B 80/00; H10W 70/614; H10W 70/635; H10W 90/10; H10W 90/724

(57) ABSTRACT

An apparatus is provided, wherein the apparatus includes a first integrated circuit (IC) device and a second integrated circuit (IC) device mounted on and electrically coupled to an interposer. The interposer includes a plurality of conductive channels, including a first plurality of conductive channel segments communicatively coupled to the first IC device and a second plurality of conductive channel segments communicatively coupled to the second IC device. The interposer further includes a plurality of embedded active components, such as embedded buffers, wherein each of the plurality of embedded active components is communicatively coupled between a respective one of the first plurality of conductive channel segments and a respective one of the second plurality of conductive channel segments.

### CROSS-REFERENCE TO RELATED APPLICATIONS

This application claims priority to U.S. Provisional Application No. 63/780,890, filed Mar. 31, 2025, which is incorporated by reference herein in its entirety.

### BACKGROUND OF THE INVENTION

### Field of the Invention

The present disclosure relates generally to the field of semiconductor devices. More specifically, embodiments of the present disclosure relate to enhanced communication interfaces between integrated circuit devices.

### Description of the Related Art

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light and not as admissions of prior art.

As semiconductor devices, such as integrated circuit (IC) devices, have increased in density and functionality, additional challenges related to fabrication, architecture, communication, power, etc., have arisen. In certain apparatuses or systems, IC devices and other system components may be arranged both horizontally adjacent to one another and vertically adjacent to one another. Vertical stacking of system components, such as IC devices, allows for greater density and functionality within a smaller footprint than might be possible in a planar device having each IC device and system component mounted on the same surface. However, regardless of the system architecture and arrangement of components with respect to one another, communication between IC devices is critical. Accordingly, it is important to provide sufficient communication paths for signals to allow the IC devices and the system, as a whole, to function as intended. Further, adding functionality and density to a system may increase the length of the communication paths between certain system components. As demand for faster transmission speeds through longer communication paths increases, maintaining signal strength throughout the communication path may become more challenging. Maintaining sufficient signal strength through the chip-to-chip communication path (e.g., IC device to IC device communication path) may be particularly challenging in certain systems.

### BRIEF DESCRIPTION OF THE DRAWINGS

Various aspects of this disclosure may be better understood upon reading the following detailed description and upon reference to the drawings in which:

FIG. 1 is a block diagram of an apparatus including integrated circuit devices communicatively coupled to one another through an interposer having embedded active components, according to an embodiment of the disclosure;

FIG. 2 is a partial perspective side view of an example of one embodiment of the apparatus of FIG. 1;

FIG. 3 is a schematic diagram of the embedded buffer of FIG. 2, in accordance with one embodiment of the disclosure;

FIG. 4 is an alternative embodiment of the embedded buffer of FIG. 3, according to an embodiment of the disclosure;

FIG. 5 is another alternative embodiment of the embedded buffer of FIG. 3, according to an embodiment of the disclosure;

FIG. 6 is another alternative embodiment of the embedded buffer of FIG. 3, according to an embodiment of the disclosure; and

FIG. 7 is a simplified top perspective view illustrating one embodiment of the arrangement of embedded buffers of FIG. 2, according to an embodiment of the disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As previously described, in certain apparatuses or systems, IC devices and other system components may be arranged both horizontally adjacent to one another and vertically adjacent to one another to allow for greater density and system functionality within a smaller footprint that might be possible in a planar device having each IC device and system component arranged on the same surface. However, providing an adequate number of communication paths between IC devices, without significant signal losses through each channel may be challenging. For instance, the IC devices in certain systems might include a memory device and a processor, wherein each of the memory device and the processor are communicatively coupled to one another through a communication interface, such as an interposer. An interposer provides a physical communication interface that electrically connects different system components, such as IC devices. Each IC device may have many input/output (I/O) pins that provide signals to and from other IC devices, through the interposer, thereby spreading the smaller chip connections (I/O pins) of each IC device to a wider pitch and facilitating higher-density interconnects.

In one embodiment, one IC device may be a High Bandwidth Memory (HBM) device and another IC device may be a System on Chip (SoC) device having one or more microprocessors. The HBM may have 1000 or more I/O pins (e.g., HBM3e), 2000 or more I/O pins (e.g., HBM4) or any number of highly dense I/O pins. Based on the density of the HBM and SoC, there may be long communication paths or channels through the interposer between the I/O pins of each of the IC devices. Because the maximum data rate through the interposer is a function of channel length, longer channels generally reduce the maximum data rate possible through the channels. Thus, while interposers are useful as a communication interface to provide communication channels between various components having densely populated I/O pins that may vary from chip-to-chip (i.e., IC devices having various form factors), typical interposers only provide conductive paths for communication between I/O devices and enable fanout from the bottom of each I/O device, without compensating for signal loss or reduced data rates through the conductive paths. Thus, the interposer might reduce the maximum data transfer rates of the IC devices that would otherwise be possible.

In accordance with embodiments provided herein, embedded active components (e.g., embedded buffers) are included within each channel of the interposer to increase signal strength through the entirety of the communication path. By positioning embedded active components (e.g., embedded buffers) within a channel, each channel may be broken into shorter channel segments to effectively reduce the total length of each channel. By placing at least one embedded active component (e.g., embedded buffer) in each channel, the reduction in signal strength is mitigated because the length of each channel segment is less than the overall length of the channel. That is, because each embedded buffer is arranged within a channel to receive a signal through a first channel segment and output a regenerated or amplified signal through a second channel segment, the losses and reduction in data transfer rate are mitigated. Thus, by utilizing an embedded active component configured to regenerate or amplify a signal through each channel, higher data rates may be achieved through each channel, utilizing the same system architecture, and without the need to change the arrangement or design of I/O pins on the IC devices (e.g., HBM and SoC), by compensating for losses through the channel. Other circuitry may be added to the embedded buffers to enhance efficiency even further.

Additionally, interposers are also configured to provide power from a power supply to each of the IC devices coupled to the interposer. Interposers are also configured to provide one or more ground planes coupled to a ground source. Because a typical interposer without embedded active components includes power and ground paths, the power and ground already supplied to the interposer can be utilized during operation of the embedded active components included in the channels of the interposer, in accordance with the disclosed embodiments.

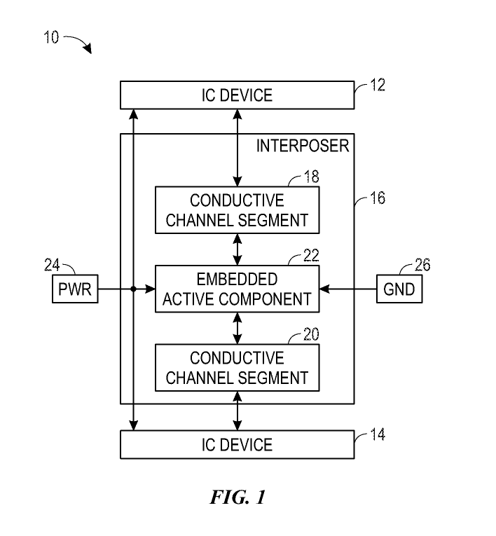

Turning now to the figures, FIG. 1 is a block diagram of an apparatus 10 (e.g., system) including integrated circuit devices 12 and 14 communicatively coupled to one another through a communication interface, such as an interposer 16. As previously described, the interposer 16 is configured to provide independent communication paths (i.e., conductive channels) between each integrated circuit device 12 and 14. In accordance with the embodiments described in FIG. 1, each conductive channel is broken into two conductive channel segments 18 and 20, communicatively coupled through an embedded active component 22. Thus, as used herein, a “channel” includes one or more “channel segments,” wherein each of the channel segments of a channel are communicatively coupled to one another through an embedded active component. Each conductive channel is a bi-directional channel that provides a communication path between the IC device 12 and the IC 14. The interposer 16 includes many channels (e.g., 2000 channels) configured to carry signals between the IC device 12 and the IC device 14. The number of channels depends on the particular IC devices 12 and 14 of the apparatus 10, and the number of I/O pins available on each IC device 12 and 14.

By way of illustration, a single conductive channel is described. As illustrated in FIG. 1, the IC device 12 is communicatively coupled to the conductive channel segment 18. Similarly, the IC device 14 is communicatively coupled to the conductive channel segment 20. As will be appreciated, I/O pins or pads (not shown) on each IC device 12 and 14 may be coupled to pads or traces of the interposer 16 through any suitable conductive interconnect, such as wirebonds, pins, leads, tabs, ball grid arrays (BGAs), micro bumps, controlled collapse chip connections (C4) bumps, or the like.

Each IC device 12 and 14 may be any packaged or unpackaged IC or chiplet, though as will be discussed further below, the disclosed embodiments may provide the most benefit to high speed IC devices having a high number of I/O pins in a densely populated area of the device. For instance, the IC device 12 may be a memory device, such as a high bandwidth memory (HBM) device. For instance, the HBM device might be any generation of HBM (i.e., HBMx) device, such as an HBM, HBM2, HBM3, HBM3e, HBM4, HBM4e, HBM5 or any future generation of HBM devices. As will be appreciated, each HBM device may include an interface die (or base die) and one or more dies stacked on the interface die to form a vertically stacked three-dimensional (3D) HBM cube. The interface die includes a physical interface (PHY) having I/O pins to communicate with other devices, such as the IC device 14, through a communication interface, such as the interposer 16. The interface die of an HBM also includes circuitry to communicate with the other dies of the HBM die stack, as will be appreciated.

Further, in one embodiment, the IC device 14 may include one or more processors, microprocessors, central processing units (CPUs), or the like. One such IC device 14 is a System-on-Chip (SoC). As will be appreciated, an SoC includes one or more CPUs, memory, graphics processing units (GPUs), and any other components that may be useful for a particular application. The SoC includes I/O pins to communicate with other devices, such as the IC device 12, through a communication interface, such as the interposer 16. In certain embodiments, the IC device 14 may include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD’s), MultimediaMediaCards (MMC’s), SecureDigital (SD) cards, CompactFlash (CF) cards, or any other suitable device. Further, the IC device 14 may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface.

As illustrated in FIG. 1, the communication interface of the disclosed apparatus 10 is an interposer 16. The interposer 16 provides both a physical interface between the IC devices 12 and 14 (e.g., the IC devices 12 and 14 are mounted directly or indirectly on the interposer 16), as well as the communication interface to electrically connect the IC device 12 to the IC device 14. Advantageously, the interposer 16 can spread smaller I/O connections on the IC device 12 and the IC device 14 to a wider pitch and facilitate the high-density interconnects of those devices. The interposer 16 may be made of silicon (Si), organic material, glass, or any other suitable material.

As described, each channel of the interposer 16 includes two or more conductive channel segments 18 and 20. Each conductive channel segment 18 and 20 may include one or more conductive traces (e.g., aluminum). In accordance with one embodiment, each conductive channel segment 18 and 20 (or each conductive trace of each channel segment 18 and 20) may have a length in the range of approximately 4mm - 7mm and a width in the range of approximately 1µm – 5µm. Further, the interposer 16 may include multiple stacked signal layers formed therethrough. Accordingly, each conductive channel segment 18 and 20 may be partially formed on different layers and the conductive traces of each conductive channel segment 18 and 20 may be communicatively coupled to one another through conductive vias. For instance, to provide an electrical coupling between conductive traces on multiple layers of the interposer, Through-Wafer Interconnects (TWIs) may be utilized. If the interposer is silicon-based, these may also be referred to as Through-Silicon Vias (TSVs). Each TSV includes a conductive material (e.g., copper) deposited within an opening to electrically couple a conductive trace on one layer of the interposer 16 to a conductive trace on another layer of the interposer 16. Thus, each conductive channel segment 18 and 20 may include one or more conductive traces located on one layer of the interposer 16, or may include one or more conductive traces located on multiple layers of the interposer 16 and electrically coupled to one another by conductive TSVs.

As discussed, every millimeter of length of a channel creates more signal loss through the channel, thus reducing the maximum possible data rate through the channel. Thus, in accordance with the present embodiments, the effective length of each communication path (i.e., channel) between the IC device 12 and the IC device 14 may be reduced by adding an embedded active component 22, such as an embedded buffer, to each channel of the interposer 16. For instance, if the embedded active component 22 is positioned in approximately the middle of the channel, the effective length of the channel is cut in half. That is, if the embedded active component 22 is in the middle of the channel, the lengths of each of the conductive channel segment 18 and the conductive channel segment 20 are approximately equal, and collectively form the full length of channel. Because the embedded active component 22 is configured to regenerate or amplify a signal through each channel, the signal strength will be regenerated at the embedded active component 22, thereby greatly reducing any losses through the first half of the channel (i.e., through either the conductive channel segment 18 or 20).

To control the embedded active component 22, power is provided from a power source 24. Advantageously, power is provided from the power source 24 to each of the IC device 12 and IC device 14 through the interposer 16. Accordingly, no additional connections from the power source 24 are necessary to provide power to the embedded active component 22. Similarly, ground planes and traces in the interposer 16 are also coupled to a ground source 26. Thus, no additional connections from the ground source 26 are necessary to provide ground to the embedded active component 22.

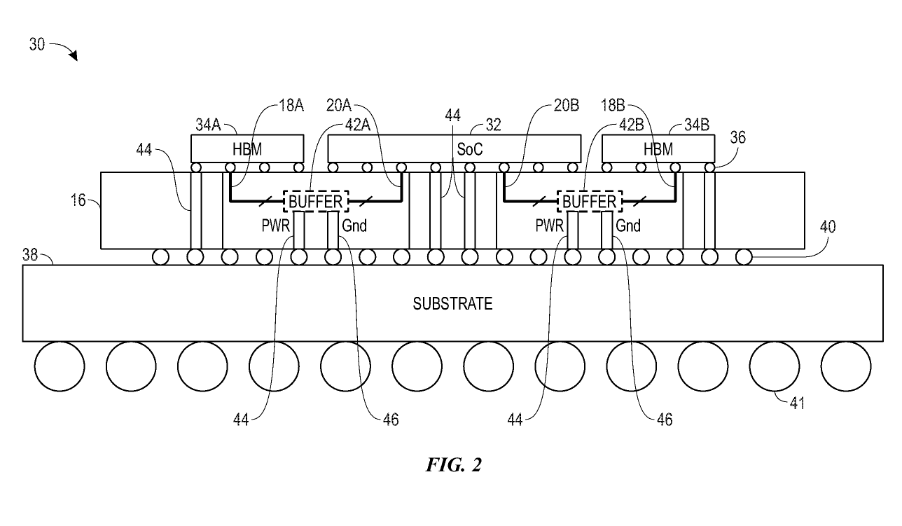

FIG. 2 is a partial perspective side view of an example of one embodiment of the apparatus 10 of FIG. 1. Specifically, FIG. 2 illustrates an apparatus 30, having three IC devices mounted on, and electrically coupled to, the interposer 16. In the illustrated embodiment, the apparatus 30 includes an SoC device 32, a first HBM 34A and a second HBM 34B coupled to the interposer 16 through electrical connections, such as micro bumps 36. As previously discussed, while the apparatus 30 includes HBM and SoC chips, any suitable die may be included in the apparatus. As will be appreciated, micro bumps 36 may provide an electrical connection between the I/O pins on each of the SoC 32, HBM 34A and HBM 34B and the interposer 16. The apparatus 30 may include other components that may be useful in a particular system. Accordingly, the apparatus 30 also includes a substrate 38 on which one or more interposers 16 may be mounted and electrically coupled through electrical connections such as solder balls 40. Still further, the substrate 38 may be mounted on and electrically coupled to another device through C4 bumps 41, for example. While particular interconnects such as micro bumps 36, solder balls 40 and C4 bumps 41 are depicted in the apparatus 30, other types of surface mount techniques may be utilized to physically and electrically couple other components to the apparatus 30.

As described above, the SoC 32 may include one or more CPUs, memory, graphics processing units (GPUs), and any other components that may be useful for a particular application. Each HBM 34A and 34B may include an interface die (or base die) and one or more dies stacked on the interface die to form a vertically stacked three-dimensional (3D) HBM cube. The interposer includes one or more embedded active components 22, such as embedded buffers 42A and 42B, as will be described further below. The HBM 34A may be communicatively coupled to the SoC 32 through conductive channel segment 18A, the embedded buffer 42A and the conductive channel segments 20A. The HBM 34B may be communicatively coupled to the SoC 32 through conductive channel segment 18B, the embedded buffer 42B and the conductive channel segments 20B. As previously described with reference to FIG. 1, each IC device 12 and 14 receives power and ground from an external power source 24 and ground source 26. For illustrative purposes, in FIG. 2, power 44 is provided from a power source (not illustrated) via the substrate 38, through the interposer 16 to each of the SoC 32, HBM 34A and HBM34B. In addition, power 44 and ground 46 are provided through the interposer 16 to each embedded buffer 42A and 42B.

As previously described, because the maximum data rate through the interposer 16 is a function of the length of each signal path (i.e., channel) communicatively coupling one IC device 12 to another IC device 14, overall channel length may disadvantageously reduce the maximum possible data rate for particular IC devices. One such device is an HBM, such as the HBMs 34A and 34B (collectively, HBM 34). Based on system standards, each HBM has a maximum data transfer rate, that may be reduced by losses through the channel. Thus, the longer the channel, the slower the data transfer rate. For instance, an HBM3 device has a maximum data transfer rate of 6.4 Gigabits per second per I/O pin (i.e., 6.4 Gbps/pin). HBM3e provides faster transfer rates of up to 8 Gbps/pin. Next-generation HBM4 devices are expected to exceed 10 Gbps/pin, while HBM4e devices are expected to potentially exceed 12 Gbps/pin.

In simulations, using the same I/O circuitry for HBM4e devices having more than 2000 I/Os, for example, data rates exceeding 20 Gbps are not possible through channels greater than 5mm in overall length. Data rates exceeding 20 Gbps may be difficult to achieve, even at 5mm, though higher transfer rates may be possible as the channel lengths are reduced. In simulations mimicking expected capabilities of HBM4e devices, maximum data rates of approximately 12 Gbps were attained through a channel with a length of 5mm. Possible data rates diminished approximately linearly to less than 10 Gbps at a channel length of 7mm, thereby limiting the desired capabilities of the device.

To mitigate the dilatory effects of channel length, embedded buffers 42A and 42B (collectively, embedded buffers 42) may be positioned at an intermediary point within the channel, thereby dividing the channel length into two or more segments, wherein the sum of the length of each channel segment in a channel equals the overall length of the conductive channel. Thus, a 5 mm conductive channel, may be split into two 2.5mm conductive channel segments (e.g., conductive channel segments 18 and 20) having an embedded buffer 42 to boost the signal through the channel at the approximate mid-point. In the simulations described above, for expected capabilities of future HBM devices, maximum data rates of approximately 21 Gbps were attained through a channel with a total length of 5mm. Possible data rates diminished approximately linearly to 18 Gbps at a channel length of 6.5mm, thereby demonstrating the advantages of the embodiments described herein. By utilizing embedded active components 22, such as embedded buffers 42, in each channel between the HBM 34 and the SoC 32, maximum data transfer rates are advantageously improved, relative to channels having now embedded active components 22 therein.

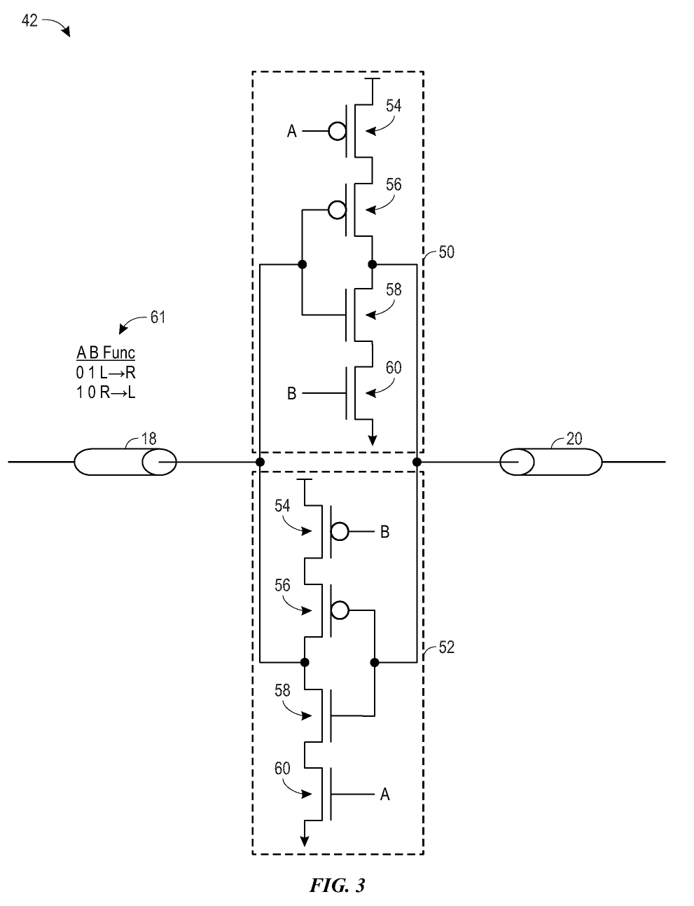

FIG. 3 is a schematic diagram of an embedded buffer 42, in accordance with one embodiment provided herein. The embedded buffer 42 is a bi-directional buffer including two buffers 50 and 52 coupled between conductive channel segments 18 and 20 to provide bi-directional communication between IC devices 12 and 14 on the interposer 16. Each buffer 50 and 52 includes a pair of p-channel metal-oxide-semiconductor field-effect transistors (MOSFETs) 54 and 56 and a pair of n-channel MOSFETs 58 and 60. Each buffer 50 and 52 is also coupled to power 44 and ground 46. As illustrated, the operation of the embedded bi-directional buffer 42 is enabled and disabled utilizing control signals A and B and in accordance with the truth table 61. Data may be transferred from the conductive channel segment 18 to the conductive channel segment 20 through the embedded buffer 42, thereby amplifying/restoring the signal to full strength. Similarly, data may be transferred from the conductive channel segment 20 to the conductive channel segment 18 through the embedded buffer 42, thereby amplifying/restoring the signal to full strength.

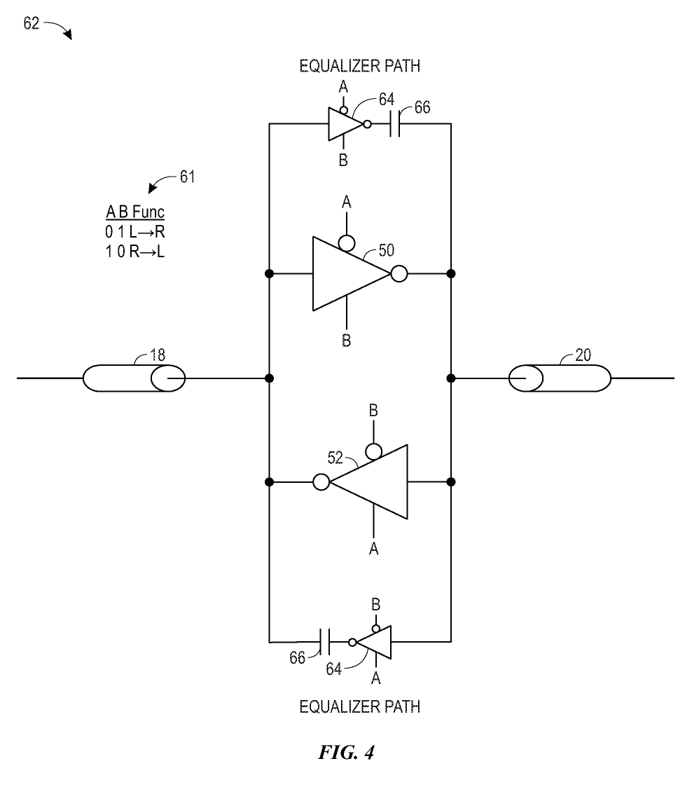

To further improve and control the data signals being transmitted through the channel, equalization techniques may be used to compensate for distortions and other signal degradation by boosting the high-frequency components of the signal to further restore the shape of the original transmission signal. For instance, FIG. 4 illustrates an embedded active component 62 having buffers 50 and 52 (illustrated using a general buffer symbol, for simplicity). In addition, continuous time linear equalization (CTLE) is used to improve the signal quality through the channel. For instance, each equalizer path includes an additional buffer 64 and a capacitor 66 to reduce distortion through the channel. Each equalizer path may further improve the signal strength through the channel and help to reduce potential inter-symbol interference (ISI) between adjacent channels. The capacitors 66 may be trench capacitors embedded in the interposer 16, for instance. As will be appreciated, while the additional buffers 64 of the embedded active component 62 are depicted as sharing primary directional control signals A and B to operate the buffers 64 in accordance with the truth table 61, independent control signals could also be used to enable/disable the buffers 64.

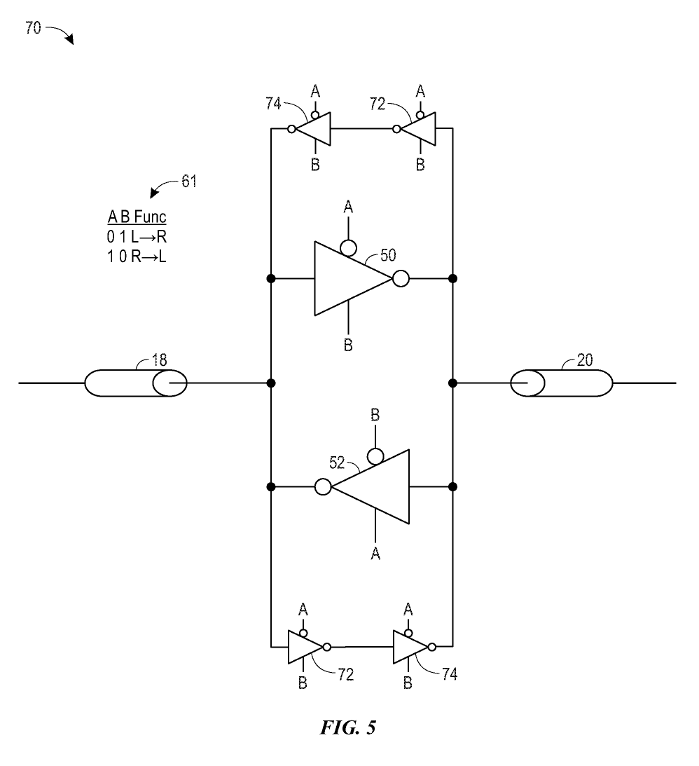

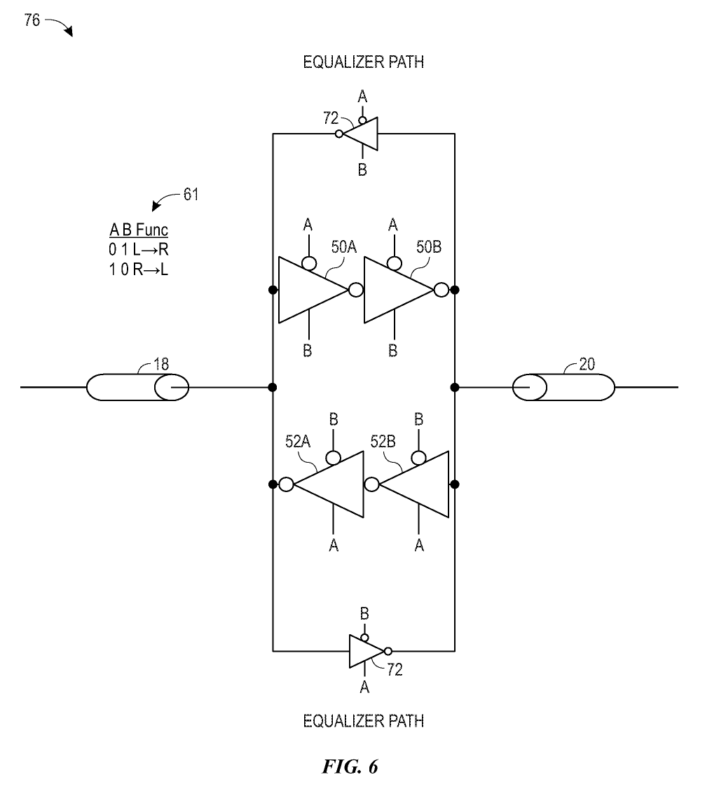

FIG. 5 illustrates another embodiment of an embedded active component 70, having buffers 50 and 52 and including feedback equalization to utilize the received signal to further improve signal quality. For instance, each equalizer feedback path includes head/footer devices, such as buffers 72 and 74. The buffers 72 and 74 could be further replicated to allow digital strength control. As will be appreciated, while the header/footer buffers 72 and 74 of the embedded active component 70 are depicted as sharing primary directional control signals A and B to operate the buffers 72 and 74, independent control signals could also be used to enable/disable the buffers 72 and 74. For instance, the buffers 72 and 74 may instead receiving varying control voltage to allow analog strength control. In the alternative embodiment of FIG. 6, a non-inverting implementation of feedback equalization is illustrated. Thus, the embedded active component 76 includes buffers 50A and 50B and a buffer 72 in the header feeback path, and buffers 52A and 52B and a buffer 72 in the footer feedback path.

As previously described, the interposer 16 may include several signal, ground and power layers. In particular, each conductive channel segment 18 and 20 may include conductive metal traces on one or more layers (i.e., in the z-direction from the top to the bottom of the interposer 16) formed through the interposer 16. Similarly, the embedded active components 22 may be located in a different layer of the interposer 16 than the conductive traces. For instance, the active components 22 may be positioned below (z-direction) a layer of the conductive traces of a particular conductive channel segment 18 and 20 and coupled to the conductive channel segments 18 and 20 by TWIs (e.g., TSVs). Thus, the active components 22 may be arranged in various relative layers of the interposer 16, in accordance with alternative embodiments.

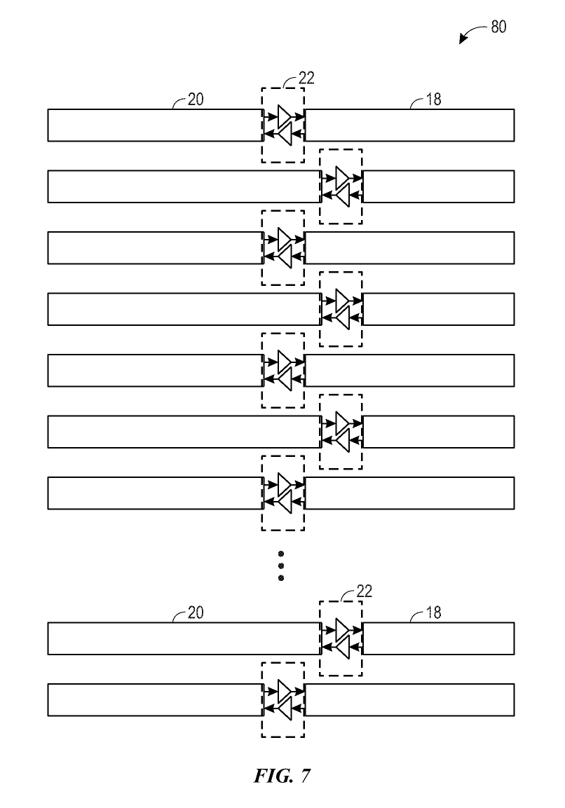

As described, the embedded active components 22 may be formed in a layer that is different from (i.e., above or below in the z-direction) the layers in which the conductive channel segments 18 and 20 are formed. In addition, in one embodiment, each embedded active component 22 coupled between a respective pair of conductive channel segments 18 and 20 may be formed in a staggered fashion relative to adjacent channels, along the length of the channel segments 18 and 20. For instance, FIG. 7 is a top perspective view illustrating an arrangement of the embedded active components 22, in accordance with one embodiment of the disclosure. As illustrated, the embedded active components 22 (e.g., embedded buffers 42) are formed below the layer of conductive traces that form the conductive channel segments 18 and 20. Each embedded active component 22 is coupled to an overlying pair of conductive channel segments 18 and 20 by TWIs (e.g., TSVs), as described above. In addition, each embedded active component 22 is located at approximately the mid-point of the overall length (i.e., x-direction) of the channel formed by each pair of conductive channel segments 18 and 20.

To provide enough space for the footprint of each embedded active component 22 to fit within the pitch of adjacent channels, the embedded active components 22 may be staggered such that each embedded active component 22 is staggered or shifted relative to those embedded active components 22 coupled to channels directly adjacent to one another in the y-direction of the channel array of the interposer 16. For instance, the arrangement of embedded active components illustrated in FIG. 7 forms a “zig zag” pattern wherein every other embedded active component 22 is shifted in the x-direction relative to adjacent embedded components 22, such that alternating embedded active components 22 are formed in the same plane in the y-direction, across the channel array 80. In other embodiments, other staggered arrangements may be employed. For instance, groups of embedded active components 22 may form one or more “V-shaped” or “wave” patterns across the channel array in the y-direction.

While the illustrated embodiments include only a single embedded active component 22 (e.g., embedded buffer 42) utilized to re-drive the signal through each channel, other embodiments may include multiple embedded active components 22 for each corresponding channel. That is, rather than arranging an embedded active component 22 at the approximate mid-point of a channel, thereby dividing a channel into two channel segments 18 and 20, two or more embedded active components 22 may be coupled to a single channel. For instance, a channel may include two embedded active components 22 along the channel length, each arranged at approximately one-third of the length of the channel, thereby dividing the channel into three conductive channel segments. Any suitable number of active components 22 may be electrically coupled to a single channel, thereby dividing the channel into multiple corresponding channel segments.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An apparatus, comprising:
a first integrated circuit (IC) device;
a second integrated circuit (IC) device; and
an interposer comprising:
a first plurality of conductive channel segments communicatively coupled to the first IC device;
a second plurality of conductive channel segments communicatively coupled to the second IC device; and
a plurality of embedded active components, wherein each of the plurality of embedded active components is communicatively coupled between a respective one of the first plurality of conductive channel segments and a respective one of the second plurality of conductive channel segments.

2. The apparatus of claim 1, wherein each of the plurality of embedded active components comprises a bi-directional embedded buffer.

3. The apparatus of claim 1, wherein each respective embedded active component of the plurality of embedded active components is staggered relative to each of the plurality of embedded active components directly adjacent to the respective embedded active component.

4. The apparatus of claim 1, wherein each of the plurality of embedded active components is configured to receive power from a power source and ground from a ground source.

5. The apparatus of claim 4, wherein each of the first IC device and second IC device is configured to receive power from the power source through the interposer.

6. The apparatus of claim 1, wherein the interposer comprises a silicon (Si) interposer.

7. The apparatus of claim 1, wherein each of the first plurality of conductive channel segments and the second plurality of conductive channel segments comprises one or more conductive traces and one or more through-wafer vias (TWVs).

8. The apparatus of claim 1, wherein each of the first plurality of conductive channel segments and each of the second plurality of conductive channel segments comprises a length in the range of 4mm – 7mm.

9. The apparatus of claim 1, wherein each of the first plurality of conductive channel segments and each of the second plurality of conductive channel segments comprises a width in the range of 1µm – 5µm.

10. The apparatus of claim 1, wherein the first plurality of conductive channel segments and the second plurality of conductive channel segments each comprise at least 1000 conductive channel segments.

11. The apparatus of claim 1, wherein the first plurality of conductive channel segments and the second plurality of conductive channel segments each comprise at least 2000 conductive channel segments.

12. The apparatus of claim 1, wherein the first IC device comprises a memory device.

13. The apparatus of claim 12, wherein the memory device comprises a High Bandwidth Memory (HBM) device.

14. The apparatus of claim 12, wherein the second IC device comprises a microprocessor.

15. The apparatus of claim 1, wherein:
each of the first plurality of conductive channel segments comprises a conductive trace arranged parallel to one another in a first plane of the interposer, and comprises a first pitch relative to one another; and
each of the plurality of embedded active components is arranged in a second plane below the first plane, and comprises a footprint that is less than the first pitch.

16. An apparatus, comprising:
a first integrated circuit (IC) device;
a second integrated circuit (IC) device; and
an interposer comprising:
a first plurality of conductive channel segments communicatively coupled to the first IC device;
a second plurality of conductive channel segments; and
a plurality of bi-directional embedded buffers, wherein each of the plurality of bi-directional embedded buffers is communicatively coupled between a respective one of the first plurality of conductive channel segments and a respective one of the second plurality of conductive channel segments.

17. The apparatus of claim 16, wherein the second plurality of conductive channel segments is communicatively coupled to the second IC device.

18. The apparatus of claim 16, wherein the first IC device comprises a High Bandwidth Memory (HBM) device.

19. The apparatus of claim 16, comprising:
a third plurality of conductive channel segments communicatively coupled to the second IC device; and
a second plurality of bi-directional embedded buffers, wherein each of the second plurality of bi-directional embedded buffers is communicatively coupled between a respective one of the second plurality of conductive channel segments and a respective one of the third plurality of conductive channel segments.

20. The apparatus of claim 16, wherein each respective bi-directional embedded buffer of the plurality of bi-directional embedded buffers is staggered relative to each of the plurality of bi-directional embedded buffers directly adjacent to the respective bi-directional embedded buffer, and wherein the plurality of bi-directional embedded buffers forms a zig-zag pattern across an array of the first plurality of conductive channel segments.

21. The apparatus of claim 16, wherein each of the plurality of bi-directional embedded buffers comprises equalization components.

22. The apparatus of claim 21, wherein the equalization components comprise trench capacitors.

23. The apparatus of claim 21, wherein the equalization components comprise feedback equalization components.

24. An apparatus, comprising:
a High Bandwidth Memory (HBM) device comprising a first plurality of input/output (I/O) pins;
a System-on-Chip (SoC) device comprising a second plurality of I/O pins;
an interposer, wherein each of the HBM device and the SoC device are mounted on and electrically coupled to the interposer;
a plurality of conductive channels formed in a first layer of the interposer and configured to transmit data between the first plurality of I/O pins and the second plurality of I/O pins; and
a plurality of bi-directional embedded buffers formed in a second layer of the interposer, wherein each of the plurality of bi-directional embedded buffers is electrically coupled to a respective one of the plurality of conductive channels and is configured to reduce losses through the respective one of the plurality of conductive channels.

25. The apparatus of claim 24, wherein each of the plurality of bi-directional embedded buffers is electrically coupled to a mid-point of a respective one of the plurality of conductive channels.
